(19) United States
(12) Patent Application Publication
(10) Pub. No.: US 2025/0298321 A1
(43) Pub. Date: Sep. 25, 2025

(54) MULTISCALE CONTROL OF SUBSTRATE DEFORMATION IN DEVICE MANUFACTURING

(71) Applicant: Applied Materials, Inc., Santa Clara, CA (US)

(72) Inventors: Wonjae Lee, Fremont, CA (US); Pradeep Kumar Subrahmanyan, San Jose, CA (US)

(21) Appl. No.: 19/076,106

(22) Filed: Mar. 11, 2025

Related U.S. Application Data
(60) Provisional application No. 63/567,840, filed on Mar. 20, 2024.

(51) Int. Cl. G03F 7/00

(52) U.S. Cl. CPC G03F 7/70291; G03F 7/70508; G03F 7/70558; G03F 7/70783

(57) ABSTRACT

Disclosed techniques include obtaining a map of deformation of a substrate, depositing a stress-compensation layer (SCL) on the substrate, computing a dose map for a stress-modification beam, the dose map having a first feature of a first spatial scale and a second feature of a second spatial scale. The techniques further include forming a spatially modulated mask on the SCL, the spatially modulated mask having a first modulation along a first direction and a second modulation along a second direction. The techniques further include subjecting the spatially modulated mask and the SCL to the stress-modification beam to induce a spatial modulation of stress in the SCL, the spatial modulation of stress in the SCL causing modification of the deformation of the substrate.

### RELATED APPLICATIONS

The present application claims the benefit under 35 U.S.C. § 119 (e) of the U.S. Provisional Patent Application No. 63/567,840 filed Mar. 20, 2024, entitled “MULTISCALE CONTROL OF WAFER DEFORMATION IN DEVICE MANUFACTURING,” the contents of which are being incorporated in their entirety by reference herein.

### TECHNICAL FIELD

The disclosure pertains to semiconductor manufacturing, including processing of wafers and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers can undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### SUMMARY

Disclosed herein, according to one embodiment, is a method that includes depositing a stress-compensation layer (SCL) on a substrate and determining, using a map of deformation of the substrate, a dose map for a stress-modification beam. The dose map includes a first feature having a first spatial scale along a first direction and a second feature having a second spatial scale along a second direction. The method further includes forming a spatially modulated mask on the SCL. The spatially modulated mask having a first modulation associated with the first spatial scale and a second modulation associated with the second spatial scale. The method further includes subjecting the spatially modulated mask and the SCL to the stress-modification beam to induce a spatial modulation of stress in the SCL. The spatial modulation of stress in the SCL causes modification of the deformation of the substrate.

In another embodiment, disclosed is a system that includes a memory and a processing device communicatively coupled to the memory. The processing device is to cause performance of operations that include forming an SCL on a substrate and determining, using a map of deformation of the substrate, a dose map for a stress-modification beam. The dose map includes a first feature having a first spatial scale along a first direction and a second feature having a second spatial scale along a second direction. The operations further include forming a spatially modulated mask on the SCL. The spatially modulated mask includes a first modulation associated with the first spatial scale and a second modulation associated with the second spatial scale. The operations further include subjecting the spatially modulated mask and the SCL to the stress-modification beam to induce a spatial modulation of stress in the SCL. The spatial modulation of stress in the SCL causes modification of the deformation of the substrate.

In another embodiment, disclosed is a semiconductor manufacturing system having one or more processing chambers, the semiconductor manufacturing system to form an SCL on a substrate and determine, using a map of deformation of the substrate, a dose map for a stress-modification beam. The dose map includes a first feature having a first spatial scale along a first direction and a second feature having a second spatial scale along a second direction. The semiconductor manufacturing system is further to form a spatially modulated mask on the SCL. The spatially modulated mask includes a first modulation associated with the first spatial scale and a second modulation associated with the second spatial scale. The semiconductor manufacturing system is further to subject the spatially modulated mask and the SCL to the stress-modification beam to induce a spatial modulation of stress in the SCL. The spatial modulation of stress in the SCL causes modification of the deformation of the substrate.

### BRIEF DESCRIPTION OF THE DRAWINGS

The present disclosure will be understood more fully from the detailed description given below and from the accompanying drawings of various embodiments of the disclosure.

FIG. 1A illustrates schematically a portion of a uniformly (e.g., parabolically) deformed wafer such that the stress tensor is isotropic σₓₓ≈σ_{yy}. FIG. 1B illustrates schematically a portion of a wafer having anisotropic (e.g., cylindrical) deformation such that the stress tensor is anisotropic σₓₓ>σ_{yy}. FIG. 1C illustrates an example Zernike polynomial decomposition 170 that can be used to characterize deformation of a wafer.

FIGS. 2A-2H show a wafer-wide view of a process of semiconductor manufacturing that uses directional patterns for stress modification, according to at least one embodiment.

FIGS. 3A-F illustrate schematically a process of correcting wafer deformation using a stress-modification beam applied to a stress compensation layer deposited on a back side of a wafer and partially shielded by a directional pattern, according to at least one embodiment.

FIGS. 4A-4F illustrates schematically formation of an example two-dimensional directional pattern that can be used to mitigate multi-scale stresses and the resulting deformation of wafers, according to at least one embodiment.

FIG. 5 is a flowchart illustrating an example method of mitigation of multi-scale stresses in wafers using a combination of a stress-compensation layer, a multi-scale mask, and a stress-modification beam, according to at least one embodiment.

FIG. 6 is a flowchart illustrating an example method of determining settings for beam irradiation, according to at least one embodiment.

FIGS. 7A-7B illustrates schematically an irradiation system capable of performing irradiation of stress compensation layers, according to at least one embodiment.

FIG. 8 depicts a block diagram of an example computer system capable of supporting operations of the present disclosure, according to at least one embodiment.

### DETAILED DESCRIPTION

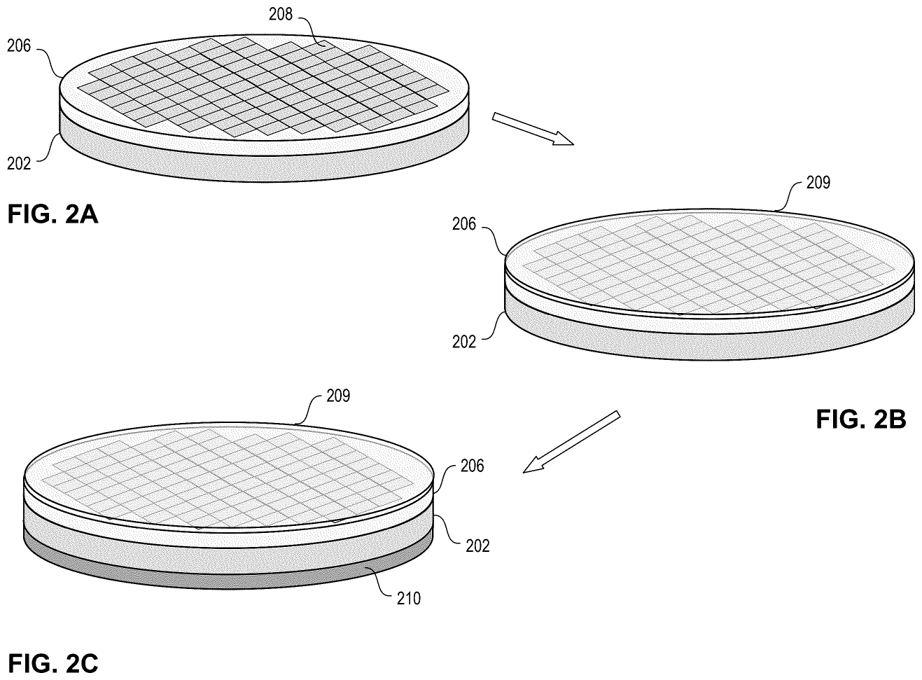

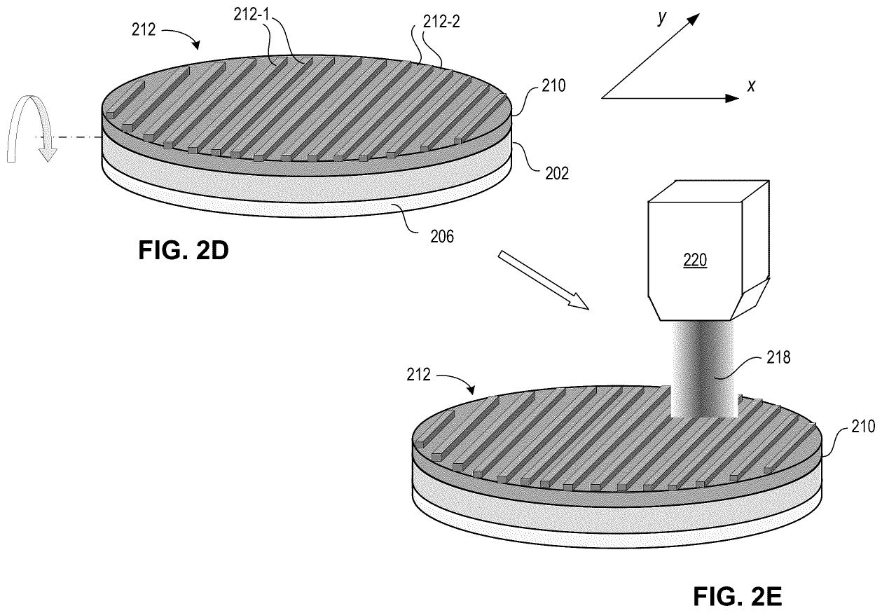

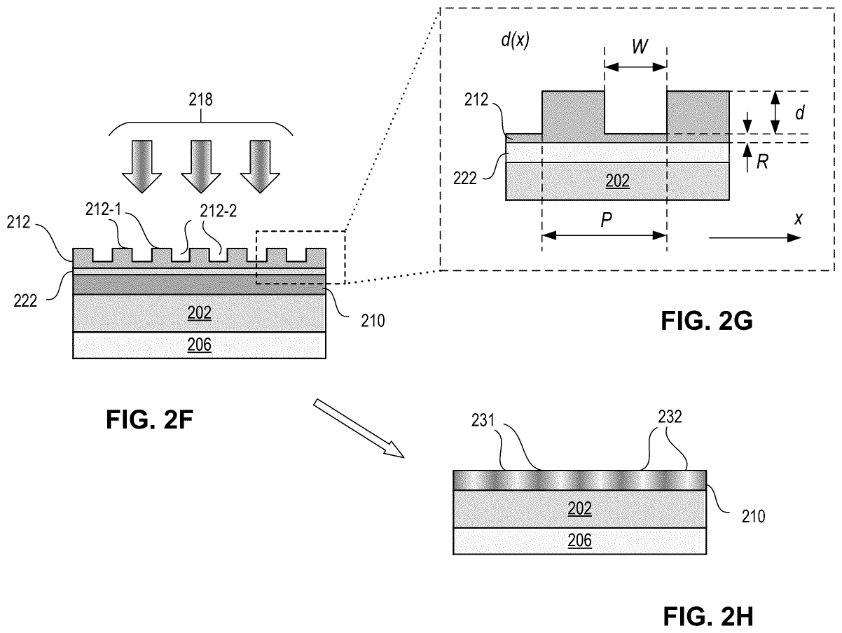

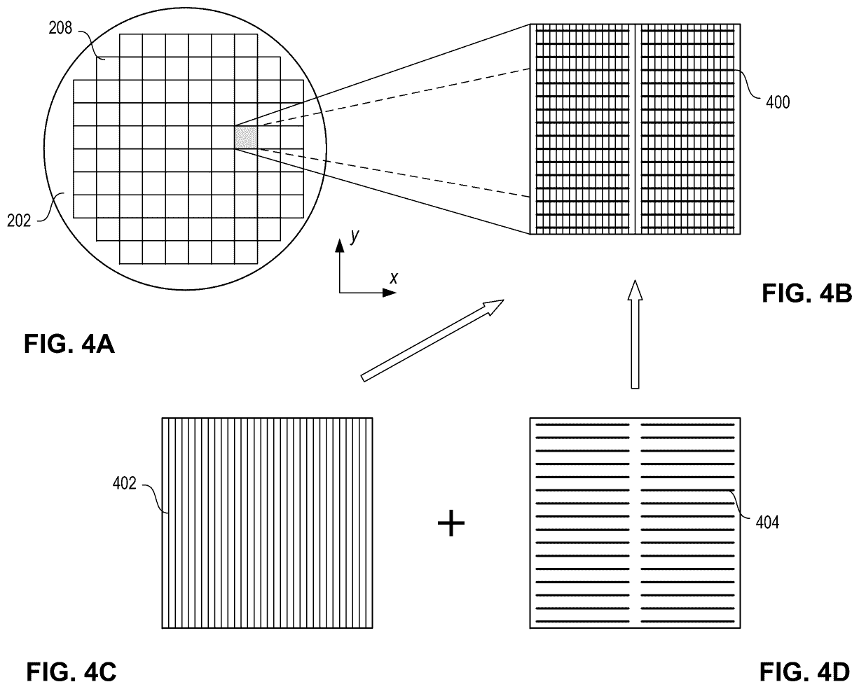

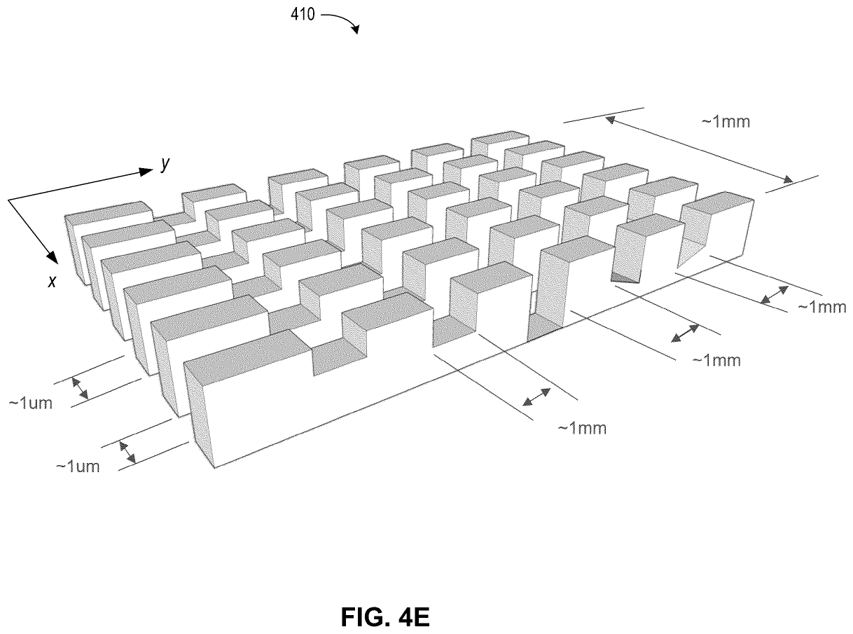

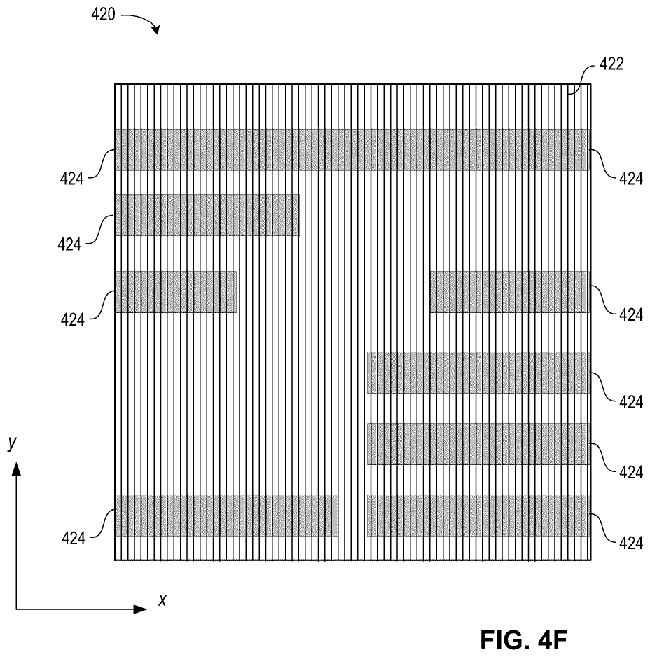

Modern technology often aims to maximize chip area utilization by manufacturing three-dimensional devices with vertical stacks of multiple layers of semiconducting structures. For example, in NAND flash memory devices, lateral relative arrangement (CMOS near Array, or CnA) of memory cells (e.g., floating gate transistors) and peripheral transistors (e.g., CMOS circuitry used to support write/read operations OF memory cells) has mostly given way to a vertical arrangement (CMOS under Array, or CuA) in which peripheral CMOS circuitry is disposed below an array of memory cells. In many instances, semiconductor structures are manufactured in an anisotropic fashion, e.g., with multiple high, long (along the direction of wordlines), and narrow (along the direction of bitlines) stacks of memory cells manufactured (deposited and/or etched) on wafers. Depositing these and other high aspect ratio structures typically results in anisotropic stresses that cause wafers to become deformed (e.g., warped). Anisotropic stresses σ(x, y) vary quickly along a “fast” direction (e.g., x axis) on a short scale λₐₙ of the order of one or several microns, which is significantly shorter than stress variations along the other, “slow,” direction (e.g., y axis). Wafer deformation can lead to misalignment of manufactured features and result in substandard or inoperable devices. Correcting the anisotropic stresses and the resulting wafer deformations is an important but difficult task. In addition to anisotropic stresses caused by directional features, various other sources of stresses can exist in wafers. For example, as illustrated in FIG. 2A and FIG. 4A, various manufactured features can be formed as part of dies, e.g., units of formed semiconducting devices. Since dies are often positioned symmetrically around the area of a wafer (substrate), the dies often cause stresses that are more isotropic than the feature-induced stresses. The die-caused stresses can have a scale λ_{die} that is larger (e.g., of the order of one to several millimeters) than λₐₙ. Further stresses can be caused by wafer-level processing, e.g., conditions in processing chamber(s) that vary slightly from wafer to wafer. Such wafer-to-wafer variations typically induce stresses that have yet longer scales, λ_{waf}, e.g., one or more centimeters.

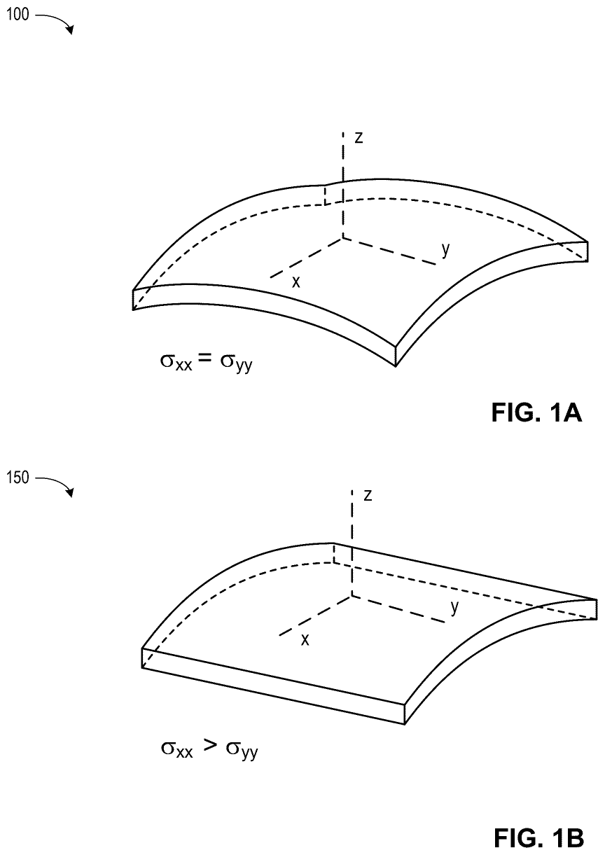

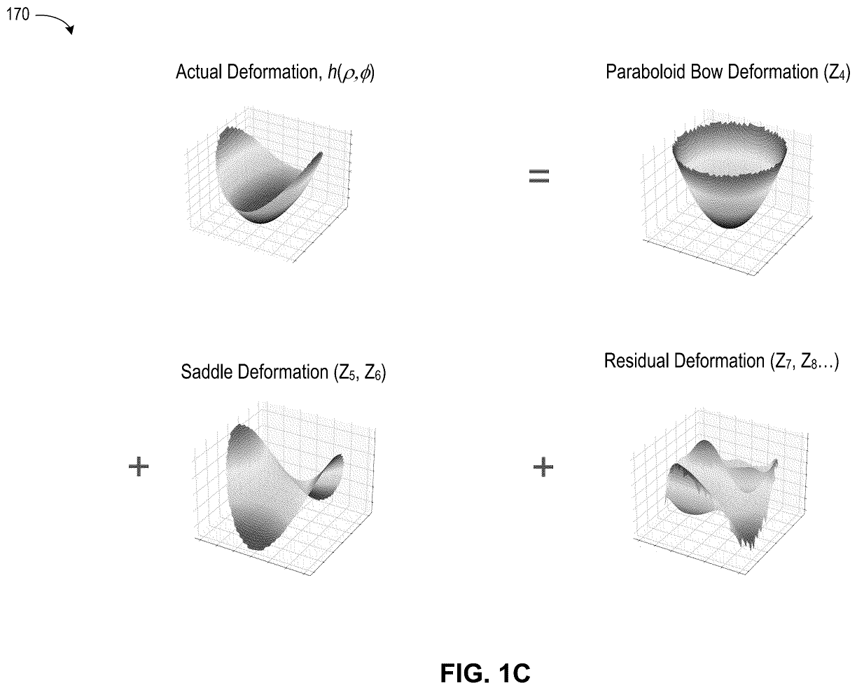

Stress modification can be achieved with deposition of a stress-compensation layer (SCL), which can be a film of a material that, being deposited on, e.g., the back side of a wafer, introduces a stress that at least partially negates the stresses caused by patterning and other features placed on the front side of the wafer. Additional control of stresses in the wafer can be achieved with ion implantation into the SCL that modifies (typically, reduces) the amount of stress in the SCL by introducing substitutions and vacancies in the physical structure of the SCL. SCLs and ion implantations can be quite efficient in correcting stresses that are uniform and isotropic, σₓₓ≈σ_{yy}, but mitigating stresses that are anisotropic, σₓₓ≠σ_{yy}, remains a challenging problem. FIG. 1A illustrates schematically a portion 100 of a uniformly (e.g., parabolically) deformed wafer such that the stress tensor is isotropic σₓₓ≈σ_{yy}. FIG. 1B illustrates schematically a portion 150 of a wafer having anisotropic (e.g., cylindrical) deformation such that the stress tensor is anisotropic σₓₓ>σ_{yy}, where y is the axis of the cylindrical deformation. In the example of FIG. 1B, the y axis is the slow axis of stress variations and the x axis is the fast direction of stress variations. For a given wafer, the orientation of the slow and fast axes may be determined using information about features formed on the wafer, such as the direction of wordlines/bitlines (which may be known from a technical specification of the performed feature deposition operations), mapping of stresses created by the features, Oxide/Nitride layers, wordline filling material(s), etc. (e.g., as determined using a physical model for the wafer stress deformation), and/or the like.

Aspects and embodiments of the present disclosure address these and other challenges of the modern semiconductor manufacturing technology by providing for systems and techniques capable of correcting isotropic and anisotropic wafer deformations illustrated in FIGS. 1A-1B. In one example embodiment, anisotropic deformations of the type illustrated in FIG. 1B, e.g., those caused by manufactured features, can be compensated by depositing, growing, or otherwise forming directional masks that include, e.g., line gratings, to partially protect a deposited SCL. The gratings can be used for partial (local) shielding (masking) of SCL from the stress-modification beam (e.g., an ion beam). The grooves/trenches can be parallel to the slow axis y of stress variations and can allow access of the particles of the stress-modification beam to the underlying areas of the SCL (stress-modified areas), where stress is significantly modified. On the other hand, the ridges of the gratings can protect other areas of the SCL where stresses remain unmitigated (or weakly mitigated). The pattern of alternating stress-modified areas and protected areas causes the wafer to experience an anisotropic deformation that compensates for the anisotropic stress patterns caused by the deposited features. In some instances, the grooves/trenches can be formed in a direction that is at some angle to the slow axis y.

Deformations of the type illustrated in FIGS. 1A-1B, e.g., those caused by die-to-die and wafer-to-wafer variations in stresses, can be efficiently corrected by varying a dose of an ion beam, which can be controlled by changing a lateral speed of the ion beam (as disclosed in more detail below), by changing a duty cycle (e.g., the durations of off and on intervals of a beam operating in a pulsed configuration), and by using additional longer-scale patterning of the masks to introduce spatial variations of the doses of stress-modification beams received by the SCL. For example, longer-scale die-to-die variations can be corrected by also patterning the masks along the slow axis y, e.g., in the direction that is parallel to the gratings. Furthermore, since die-to-die stress variations can occur along both the slow axis and the fast axis, additional patterning of the masks along the fast axis x, e.g., in the direction perpendicular to the gratings, can be used. In some implementations, gratings that address short-scale feature-caused stresses can be binary, e.g., having one of two thicknesses, dₘᵢₙ or dₘₐₓ, with minimum thickness dₘᵢₙ of the masking material placed over those areas of the SCL where stronger stress modification is desired and maximum height dₘₐₓ of the masking material placed over those areas of the SCL where weaker stress modification is intended. Subsequently, the thickness of the gratings can be further modulated, d(x, y), along the slow axis y to address die-to-die variations, with dₘᵢₙ≤d(x, y)≤dₘₐₓ. In some implementations, the thickness d(x, y) can be a continuous function of the coordinates x, y or a function having a number N>2 of discrete values, e.g., N values within the interval, [dₘᵢₙ, dₘₐₓ].

The stress-modification beam can include matter particles (e.g., ions, electrons), electromagnetic waves (e.g., UV light, visible light, infrared light, etc.), and/or a suitable combination thereof. The stress-modification beam strikes the SCL and changes the bonding network of the SCL. For example, the stress-modification beam of low energy can interact with surface atoms of the SCL, e.g., removing some of the surface atoms, effectively implementing etching of surface regions of the SCL. The effectiveness of such etching can be controlled by a choice of ion species/radicals/ambient gasses. In another example, the stress-modification beam of high energy can deposit ions inside the SCL. Ions and/or photons of the beam can break bonds of the bonding network (or crystal lattice) of the SCL forming vacancies therein, and can further cause annealing due to local heating, UV curing, and/or other effects. Substitution defects and/or vacancies created by the particles of the stress-modification beam modify (e.g., reduce) stress in the SCL and, through the SCL, in the wafer. The intensity and/or dose (the intensity integrated over time) of the stress-modification beam can vary with the location within the SCL and can be determined (e.g., simulated, modeled, etc.) in a way that maximally relieves the stress in the SCL (and, further, in the wafer). This causes the combination of the wafer, the deposited layers/films, and the SCL to flatten and facilitates precise alignment of features that are patterned on the wafer, etched in one or more stacks of layers, and/or the like, and improves quality of the manufactured devices. The intensity/doses of irradiation can be determined based on measured deformation of the wafer (with layers/films/mask deposited thereon), e.g., using various optical measurement techniques. Multiple techniques can then be used to determine optimal intensity and/or dose of the stress-modification beam, such as statistical Monte Carlo simulations, influence function computations, and/or other techniques, as disclosed below.

Advantages of the disclosed embodiments include but are not limited to correcting isotropic and anisotropic wafer deformations in manufactured semiconductor products, for more accurate alignment of features manufactured on wafers and/or other substrates.

A “wafer” or “substrate,” as used herein, refers to any substrate or material surface formed on a substrate upon which film processing is performed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, and any other materials such as metals, metal nitrides, metal alloys, and other conductive materials, depending on the application. Wafers include, without limitation, semiconductor wafers. In some instances, wafers can include plastic substrates. Wafers can be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed can also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

FIG. 1C illustrates an example Zernike polynomial decomposition 170 that can be used to characterize deformation of a wafer, according to at least one embodiment. The top left portion of FIG. 1C illustrates an example deformation h(r, ϕ) of a wafer, in arbitrary units; the top right portion of FIG. 1C illustrates a paraboloid bow component of the deformation; the bottom left portion of FIG. 1C illustrates a saddle component of the deformation; and the bottom right portion of FIG. 1C illustrates residual deformation.

In one embodiment, an amount of stress in the wafer (and films that can be deposited thereon) can be determined by measuring a vertical profile of the wafer deformation h(\vec{r}) e.g., using one or more optical inspection techniques. The profile can refer to the vertical coordinate, z=h(\vec{r}), of the top surface of the SCL or wafer/stack of films (if the measurement is performed prior to SCL deposition). For example, an interferogram of the profile h(\vec{r}) can be obtained using optical interferometry measurements. In some embodiments, the measured wafer deformation h(\vec{r})=h_{quad}(\vec{r})+hᵣₑₛ(\vec{r}) can be represented as a combination of a quadratic h_{quad}(\vec{r}) and residual (non-quadratic) hᵣₑₛ (\vec{r}) contributions. The quadratic deformation can include a parabolic (paraboloid bow) part hₚₐᵣ(r), which has the axial symmetry, and a saddle part h_{saddle}(\vec{r}).

To characterize the geometry of the wafer deformation h(\vec{r}), a suitable set of parameters can be selected. For example, a set of Zernike (or a similar set of) polynomials can be used to represent the wafer profile,

$$h ( \vec{r} ) = {\sum }_{j} {A}_{j} {Z}_{j} ( \vec{r} ) ,$$

where the planar radius-vector \vec{r}=(r, ϕ) can be represented as the radial coordinate r and the polar angle ϕ within the (average) plane of the wafer. Consecutive coefficients A₁, A₂, A₃, A₄ . . . represent weights of specific geometric features (elemental deformations) of the wafer described by the corresponding Zernike polynomials Z₁ (r, ϕ), Z₂ (r, ϕ), Z₃ (r, ϕ), Z₄ (r, ϕ) . . . . (Herein, the Noll indexing scheme for the Zernike polynomials is being referenced.) The first three coefficients are of less interest as they describe a uniform shift of the wafer (coefficient A₁, associated with the Z₁ (r, ϕ)=1 polynomial), a deformation-free x-tilt that amounts to a rotation around the y-axis (coefficient A₂, associated with the Z₂ (r, ϕ)=2r cos ϕ polynomial), and a deformation-free x-tilt that amounts to a rotation around the x-axis (coefficient A₃, associated with the Z₃ (r, ϕ)=2r sin ϕ polynomial) that can be eliminated by a realignment of the coordinate axes. The fourth coefficient A₄ is associated with Z₄ (r, ϕ)=\sqrt{3} (2r²−1) and characterizes an isotropic paraboloid bow deformation. The fifth A₅ and the sixth A₆ coefficients are associated with Z₅(r, ϕ)=\sqrt{6}r² sin 2ϕ and Z₆(r, ϕ)=\sqrt{6}r² cos 2ϕ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation, hᵣₑₛ (r, ϕ)=h(r, ϕ)−Σⱼ₌₄⁶AⱼZⱼ(r, φ).

In some implementations, the measured profile of the wafer deformation h(r, ϕ) can be used to identify the stresses that exist in the wafer, σ(r, ϕ) or σ(x, y), e.g., by solving (or modeling) the equation of elasticity (such as the thin plate equation) describing a mechanical state of the deformed wafer. In some instances, stress in the wafer can be uniform and isotropic, σₓₓ≈σ_{yy}. In some instances, stress in the wafer can be anisotropic, σₓₓ≠σ_{yy}. Certain feature patterns can result in stresses that are compressive along one direction, e.g., σₓₓ>0, and tensile along a perpendicular direction, σ_{yy}<0, resulting in saddle-shaped wafers.

In some implementations, a thickness of the stress-compensation layer (SCL) can be computed (or empirically determined) in such a way that the SCL applies a desired target stress to the wafer. To eliminate a non-uniform saddle deformation, SCL can be of such thickness/material as to turn the saddle deformation into a cylindrical deformation having a definite sign throughout the area of the wafer. The uniform-sign cylindrical deformation (as well as a residual higher-order non-quadratic deformation) can be mitigated by irradiation with a stress-modification beam. In some embodiments, a cylindrical decomposition is not unique and can be either positive (upward-facing cylindrical deformation) or negative (downward-facing cylindrical deformation). Both decompositions can be analyzed and a decomposition that allows a more effective stress modification can be selected. For example, a decomposition that is characterized by a smaller parabolic bow deformation can be selected. The parabolic bow deformation can be mitigated using a choice of SCL (e.g., type and thickness) while the remaining cylindrical deformation (and the higher-order residual deformation) can be addressed by appropriately selected ion or photon irradiation dose n(\vec{r}).

In some embodiments, mitigation of a cylindrical deformation or a saddle deformation can include identifying principal axes (directions) of the cylinder/saddle and a magnitude of the cylindric/saddle deformation and directing the stress-modification beam into appropriately selected edge regions of the SCL. In some implementations, the axes of the saddle deformation can be parallel and perpendicular to the direction of the features deposited (or otherwise formed) on the wafer.

FIGS. 2A-2H show a wafer-wide view of a process of semiconductor manufacturing that uses directional patterns for stress modification, according to at least one embodiment. FIG. 2A shows a wafer 202, which can be a bare wafer or a wafer with one or more features patterned thereon (e.g., source lines of NAND devices). In some embodiments, wafer 202 can undergo any appropriate additional treatment, such as annealing. A stack of one or more films 206 can be deposited on wafer 202. Stack 206 can include uniform (unpatterned) or patterned films. For example, a set of features 208 can be formed within at least some of films of stack 206, e.g., using photolithography and/or other techniques. Features 208 can include chip boundaries, area boundaries, slits, channels, and/or any other applicable features. In some implementations, as illustrated in FIG. 2B, a frontside protection layer 209 can be deposited to protect stack 206 during wafer handling and manipulations with various mechanical effectors.

FIG. 2C illustrates an SCL 210 deposited on the back side of wafer 202. With the back side of wafer 202 facing up, as shown in FIG. 2D, a suitable directional patterned mask 212 can be manufactured on the SCL 210. (For simplicity, FIGS. 2D-2H do not show frontside protection layer 209.) “Directional pattern,” as used herein, refers to any pattern having characteristic length scale(s) of associated features along one direction substantially exceeding, e.g., by factor 3, 5, 10, or more, a characteristic length of the features along the other direction. An example directional pattern can include gratings with a pitch of 10 nm-100 μm or more and length of lines of 10 μm-1 cm or more. In some embodiments, the directional patterned mask 212 can be made of a different material than SCL 210. For example, directional patterns can be or include a photoresist mask deposited on SCL 210. In some embodiments, the directional patterned mask 212 can be made of the same material as SCL 210. In some embodiments, the directional patterned mask 212 can be etched in SCL 210. In some embodiments, the directional pattern can include raised portions 212-1 (e.g., ridges, protrusions, elevations, etc.) and recessed portions 212-2 (e.g., trenches, grooves, ruts, dips, etc.).

As illustrated in FIG. 2E, the directional patterned mask 212 and SCL 210 can be subjected to irradiation by a stress-modification beam 218. Stress-modification beam 218 can be generated by a suitable collimating and focusing column 220. As illustrated in FIG. 2F for a portion of the wafer 202, the directional patterned mask 212 modulates the amount of irradiation that reaches SCL 210. For example, the portions of SCL 210 that are located below raised portions 212-1 of directional patterned mask 212 (protected areas) can be shielded to a higher degree than the portions of SCL 210 that are located below recessed portions 212-2 (stress-modified areas).

As further illustrated in FIG. 2F, in some embodiments, an additional coating layer 222 can be deposited between SCL 210 and directional patterned mask 212, e.g., one or more anti-reflective coating (ARC) layers or adhesion-promoting materials, such as Hexamethyldisilazane (HMDS) or similar layers. Stress-modification beam 218 can then be applied to directional patterned mask 212. In some embodiments, stress modification beam 218 can be a high-energy ion beam depositing ions inside directional patterned mask 212. In some embodiments, stress modification beam 218 can be a low-energy ion beam mitigating stress by etching regions of SCL 210 exposed by recessed portions 212-2 of directional patterned mask 212.

FIG. 2G is a cross-sectional view of an example non-limiting geometry of directional patterned mask 212, according to one embodiment. The directional patterned mask 212 illustrated in FIG. 2F has the form of a grating with a profile d(x) that includes a set of rectangular (or near rectangular) raised portions of height d, e.g., 100 nm-10 μm, and separated by trenches of width W, e.g., 100 nm-100 μm. A period of grating P (pitch) can be 200 nm-200 μm, or any other suitable value. In some embodiments, height d can be significantly larger than a residual height, d>>R.

Although FIGS. 2D-2G illustrate masks patterned along one direction d(x), mitigation of stresses caused by dies can be achieved by further patterning the masks along the second direction, d(x, y), e.g., as disclosed in more detail in conjunction with FIGS. 4A-4D.

FIG. 2H illustrates the portion of the wafer from FIG. 2F after irradiation by stress-modification beam 218. As depicted schematically in FIG. 2H, protected areas 231 of SCL 210 (indicated with darker shading) can have more residual stress than stress-modified areas 232 (indicated with lighter shading). Directional patterned mask 212 and/or coating layer 222 can then be removed after irradiation, e.g., dissolved, polished, evaporated, and/or the like. Application of stress-modification beam 218 causes stress in SCL 210 to decrease, resulting in the flattening of the structure (reduced deformation). The reduction of stress in SCL 210 also causes the stress in wafer 202 and/or stack 206 to be reduced.

As a result of operations illustrated with FIGS. 2A-2F, a spatially modulated directional patterned structure is formed in SCL 210 where regions of higher stress (e.g., protected areas 231) are interspaced with regions of lower stress (stress-modified areas 232) using a deposited directional patterned mask 212 that shields the protected areas of SCL 210 from stress-modification beam 218, e.g., a stress-modification beam of a wide cross-sectional area. In some embodiments, a spatially modulated direction pattern may be formed in SCL 210 without deposition of directional patterned mask 212. More specifically, stress mitigation beam 218 of a narrow cross-sectional area may be applied to SCL 210. For example, a UV curing laser can be used to form narrow-pitch pattern of high stress and/or low stress regions in SCL 210 directly.

In some embodiments, selection of a thickness of SCL 210 can be made based on a value of the paraboloid bow coefficient A₄. SCL 210 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). The thickness of SCL 210 can be selected to overcorrect the wafer deformation to some degree. The overcorrection can be chosen in conjunction with a type of stress-modification beam 218 (e.g., ion implants, photons, electrons, etc.), a type of implant species (e.g., ions of specific elements), energy, and dose to ensure maximum effect from the stress modification. Stress in the combined structure of the wafer, films, and the SCL can then be modified by stress-modification beam 218 that strikes SCL 210 and changes its physical structure. Substitution defects and/or vacancies created by the beam mitigate (e.g., reduce) stress in SCL 210 and can reduce the degree of stress overcorrection caused by deposition of SCL 210. This leads to flattening of wafer 202.

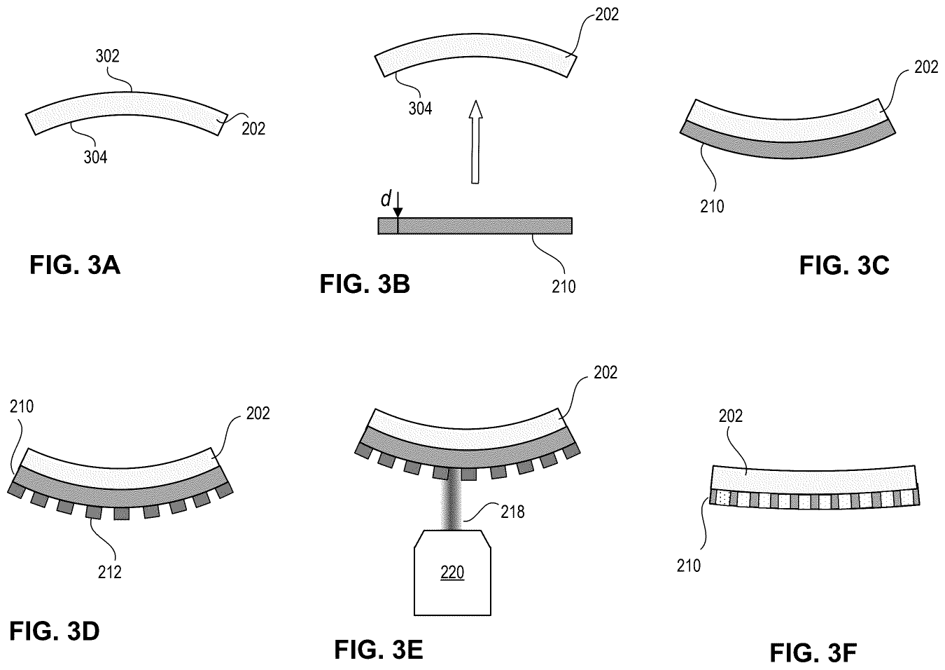

FIGS. 3A-F illustrate schematically a process of correcting wafer deformation using a stress-modification beam applied to a stress compensation layer deposited on a back side of a wafer and partially shielded by a patterned mask, according to at least one embodiment. FIG. 3A depicts a wafer 202 having a deformation, which can include a paraboloid bow deformation (with negative coefficient A₄<0, as illustrated) and can further include other deformations, such as saddle deformation, residual deformation, etc. The wafer's front side 302 can support any number of features, e.g., deposition and/or etching patterns, a stack of layers/films, and/or any other structures. FIG. 3B illustrates deposition of an SCL 210 on the back side 304 of wafer 202. In some embodiments, SCL 210 can include layers of multiple materials. In some embodiments, a material of SCL 210 can be selected in view of the sign of coefficient A₄. For example, for a negative bow, A₄<0, SCL 210 can be selected to have a compressive stress (as illustrated in FIGS. 3B-3E). For silicon wafers, such a film can be a silicon nitride (Si₃N₄) film or silicon oxide (SiO₂) film. Conversely, for a positive bow, A₄>0, SCL 210 can be selected to have a tensile stress (not shown in FIGS. 3B-3F). SCL 210 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, a thickness d of SCL 210 can be selected to overcorrect the wafer deformation to some degree, e.g., as illustrated in FIG. 3C where a negative paraboloid bow is overcorrected to a positive paraboloid bow. The thickness-dependent paraboloid bow correction A_{corr}(d) changes wafer deformation from h(r, ϕ) to h_{corr}(r, ϕ):

$${h}_{c o r r} ( r , ϕ ) = h ( r , ϕ ) + {A}_{c o r r} ( d ) \cdot {Z}_{4} ( r , ϕ ) .$$

The degree of overcorrection can be chosen in conjunction with a type and parameters (e.g., energy, dose, etc.) of a specific stress-modification beam to be used on SCL 210. The overcorrection can make the combined structure of wafer 202 and SCL 210 susceptible to further control of stress (and thus control of deformation of the wafer h_{corr}(r, ϕ)).

As illustrated in FIG. 3D, SCL 210 can be used in conjunction with a directional patterned mask 212 that provides a local shielding of SCL 210 from a stress-modification beam 218. As illustrated in FIG. 3E, collimating and focusing column 220 can generate stress-modification beam 218 that strikes SCL 210 and changes its elastic properties, e.g., by creating vacancies, breaking crystal bonds, depositing ions, and/or via any other applicable mechanisms. Stress-modification beam 218 can carry photons, electrons, silicon ions, phosphorus ions, argon ions, neon ions, xenon ions, krypton ions, and/or the like. In some embodiments, the energy and type of ions in stress-modification beam 218 can be selected to limit the implanted ions to the volume of SCL 210 without allowing the ions to reach wafer 202 (and/or any layers/films deposited on wafer 202). Ions that lodge in SCL 210 create substitution defects therein. Additionally, the ions leave a trail of vacancy defects along paths of propagation in SCL 210. The substitution defects and/or vacancies mitigate (e.g., reduce) stress in SCL 210 and can reduce the degree of stress overcorrection caused by the SCL deposition. This causes the combination of wafer 202 and SCL 210 to flatten.

In some embodiments, the number of ions ΔNᵢ deposited per small area ΔA=ΔxΔy (or the total amount of photon energy applied to this area) of wafer 202 can be determined using simulations (performed as described in more detail below) based on the local value of the corrected deformation h_{corr}(r, ϕ), which can include a saddle deformation, a residual deformation, and the part of the paraboloid bow deformation A_{corr}(d)+A₄ that has been overcorrected by the deposition of SCL 210. The target local density n(x, y)=ΔNᵢ/ΔxΔy of the ions can be delivered by controlling the scanning velocity v of stress-modification beam 218. In some embodiments, stress-modification beam 218 has a profile that can be approximated with a Gaussian function, e.g., the ion flux j(ρ)=j₀ exp(−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that has the following number of ions:

$$\frac{Δ {N}_{i}}{Δ x Δ y} = \frac{{j}_{0}}{v} {\int }_{- ∞}^{∞} dx {e}^{- {x}^{2} / {a}^{2} - {y}^{2} / {b}^{2}} = \frac{{j}_{0} \sqrt{π}}{v a} {e}^{- {y}^{2} / {b}^{2}} .$$

Correspondingly, by reducing the scanning velocity v, the number of ions received by various regions of SCL 210 can be increased, and vice versa. Additionally, stress-modification beam 218 can perform multiple scans with different offsets y so that various points of SCL 210 receive multiple doses of ions with different factors e^{-y}^{²}^{/b}^{²} that can average to a target dose. For example, after n passes of stress-modification beam 218, each made with a respective velocity vₖ at a different distance yₖ from the center of the beam to the area ΔxΔy, the total dose of ions (or amount of electromagnetic radiation) received by this area will be

$$n ( x , y ) = \frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{a {v}_{k}} .$$

As illustrated in FIG. 3F, the alternating pattern of stress-modified areas and protected areas formed in SCL 210 by the stress-modification beam and directional patterned mask 212 results in a significant mitigation of cylindrical deformation of wafer 202 and can further mitigate paraboloid and residual deformations.

In some embodiments, settings for non-uniform exposure of the SCL to the stress-compensation beam—such as the intensity and/or total amount of irradiation per various areas of the SCL—can be determined using simulations, e.g., Monte Carlo simulations or other statistical simulations. The Monte Carlo simulations can be performed for a film made of the actual SCL material(s) and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to the SCL (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of SCL(s), angles of particle incidence on the films, and/or the like.

In some embodiments, the implantation map n(\vec{r}) can be computed using an influence function G(\vec{r}; \vec{r}′) that characterizes a response (e.g., deformation) at a point \vec{r} of the wafer as caused by a point-like mechanical influence, e.g., a point-like force, applied at another point \vec{r}′ of the wafer. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer. The Green's function can be previously determined and stored as part of a dataset in a suitable representation, e.g., as a discretized set of values of the Green's function, G(\vec{r}ᵢ; \vec{r}ⱼ).

FIGS. 4A-4E illustrates schematically formation of an example two-dimensional directional pattern that can be used to mitigate multi-scale stresses and the resulting deformation of wafers, according to at least one embodiment. FIG. 4A depicts a top view of wafer 202 supporting a suitable set of features 208, e.g., dies, wordlines, bitlines, transistors, control circuitry, and/or the like, formed on a front side of the wafer. An SCL (not visible in FIG. 4A) can be deposited (or otherwise formed) on a backside of wafer 202 and can have a suitable thickness, e.g., a thickness that is sufficient to turn deformation of wafer 202 from a saddle deformation to a cylindric deformation. As described above, a saddle deformation can be represented via a combination of a cylindric deformation and a parabolic bow deformation of the opposite sign (relative to the cylindric deformation). The thickness of the SCL can be sufficiently large to compensate (or overcompensate) the parabolic bow deformation and turn the wafer deformation from saddle deformation to the cylindric deformation.

The cylindric deformation can be caused, e.g., by line-like features (of the set of features 208) directed along the slow y-axis and having a short lateral scale λₐₙ along the fast x-axis. The corresponding induced stresses σₐₙ(x) can have fast variations (on the order of the scale λₐₙ) along the x-axis and a relatively slow variation along the y-axis. Anisotropic stresses σₐₙ(x) caused by the directional features can be accompanied by additional stresses, σ_{die}(x, y), caused by various die-scale features of the set of features 208, which can be more isotropic along the x-axis and the y-axis, with scales of the same order of magnitude, λ_{die}, along both directions. Furthermore, stresses σ_{waf}(x, y) of even longer scales, λ_{waf}, can be caused by wafer-to-wafer variations in individual wafer properties and/or processing of individual wafers. As a result, the total stress in wafer 202 can be approximated as the combination of these contributions,

$$σ ( x , y ) = {σ}_{a n} ( x ; {λ}_{a n} ) + {σ}_{d i e} ( x , y ; {λ}_{d i e} ) + {σ}_{w a f} ( x , y ; {λ}_{w a f} ) ,$$

where the pertinent scales are indicated for each term. In some example non-limiting embodiments, the scales can have the following hierarchy, λₐₙ<<λ_{die}<<λ_{waf}. In some implementations, λₐₙ is less than 1 μm. In some implementations, λₐₙ less than 100 nm. In some implementations, λₐₙ is less than 10 nm. In some implementations, λ_{die} is greater than 1 μm. In some implementations, λ_{die} is greater than 10 μm. In some implementations, λ_{die} is greater than 100 μm. In one example implementation, λₐₙ˜1 nm-10 μm, λ_{die}˜1-10 mm, λ_{waf}˜1-60 cm, although various other scales are possible.

Correcting various contributions in stress σ(x, y) can be performed by controlling the doses n(x, y) delivered by the stress-modification beam to various locations of wafer 202,

$$n ( x , y ) = {n}_{a n} ( x ) + {n}_{d i e} ( x , y ) + {n}_{w a f} ( x , y ) .$$

In particular, the longest-scale variations of the stresses can be mitigated using wafer-level doses n_{waf}(x, y) that can be controlled by changing the geometric dimensions of the beam a and b and/or the scanning velocity v of the beam, n(x, y)=(j₀\sqrt{π}/va)e^{-y}^{²}^{/b}^{²}.

The shorter-scale doses nₐₙ(x) and n_{die}(x, y) can be controlled by using a mask 400 with suitably chosen spatial dimensions, as illustrated in FIG. 4B. Mask 400 in FIG. 4B can be a spatially modulated mask, e.g., patterned mask 212 depicted in FIGS. 2D-2G. In some implementations, mask 400 can be (or include) a combination of a fast-axis patterning 402, as illustrated in FIG. 4C, and a slow-axis patterning 404, as illustrated in FIG. 4D. The mask 400 can be characterized by a profile d(x, y) of the corresponding patterned mask 212 (with reference to in FIG. 2G) formed on wafer 202 or an SCL (or one or more additional films deposited on the SCL) to partially shield the SCL from the stress-modification beam and facilitate delivery of a target dose of the beam.

In some embodiments, fast-axis patterning 402 can have a suitably chosen pitch, height, and width along the x-axis to ensure that the SCL receives the dose that has a target distribution along the x coordinate, nₐₙ(x)+n_{die}(x, y). Similarly, slow-axis patterning 404 can have a suitably chosen pitch, height, and width along the y-axis to ensure that the SCL receives the dose that has a target distribution along the y coordinate, n_{die}(x, y). In some implementations, the mask 400 can be deposited in stages. At the first stage, a uniform-height d film of the mask material can be deposited on the SCL. At the second stage, a fast-axis patterning 402 can be etched, d→d(x), in the mask material. At the third stage, a slow-axis patterning 404 can be etched, d(x)→d(x, y), in the fast-axis patterning 402. In some implementations, the order of the fast-axis and slow-axis patterning can be reversed.

In some implementations, fast-axis patterning 402 d(x) that addresses short-scale feature-caused stresses can be binary, e.g., taking one of two possible values, e.g., d(x)=dₘᵢₙ or dₘₐₓ, with a minimum height dₘᵢₙ of the masking material kept over those areas of the SCL where stronger stress modification is desired and a maximum height dₘₐₓ of the masking material retained over those areas of the SCL where less stress modification is intended. In some implementations, slow-axis patterning 404 d(x, y) can be modulated continuously within the set boundaries, e.g., dₘᵢₙ≤d(x, y)≤dₘₐₓ. In some implementations, the thickness d(x, y) can be a continuous function of the coordinates x, y or a function having a number N>2 of discrete values.

FIG. 4E is an illustrative depiction 410 of a mask (e.g., mask 400 with reference FIG. 4B) having both fast-axis patterning perpendicular to the x-axis and a slow-axis perpendicular to the y-axis patterning. (This illustrative depiction is not to scale.) In some embodiments, the mask may be non-uniform along one or more spatial dimensions. FIG. 4F is another illustrative depiction 420 of a mask that includes a uniform short-scale patterning 422 along the x-axis and a longer-scale non-uniform patterning 424 along both the x-axis and the y-axis.

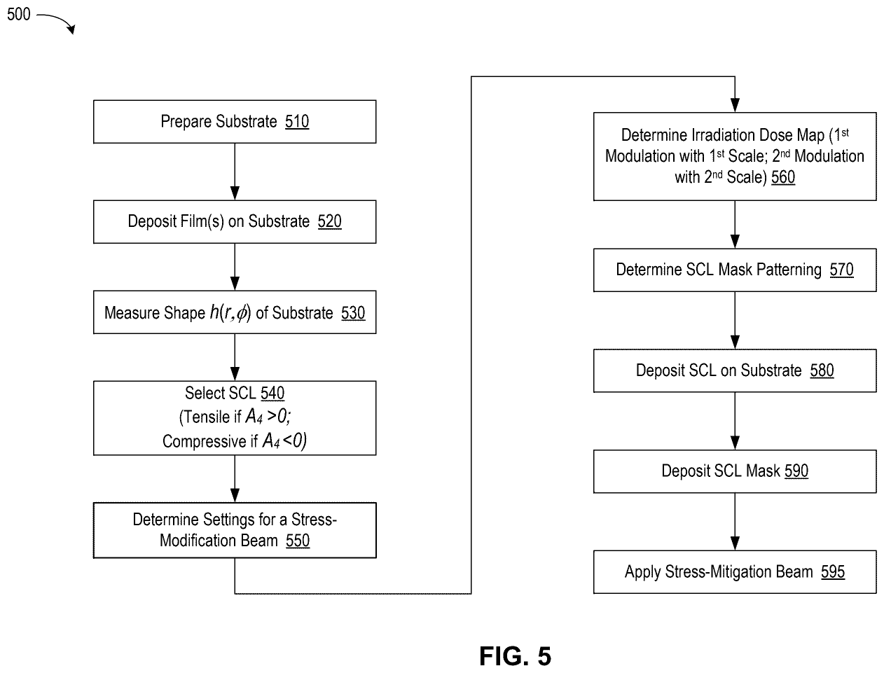

FIG. 5 is a flowchart illustrating an example method 500 of mitigation of multi-scale stresses in substrates using a combination of a stress-compensation layer, a multi-scale mask, and a stress-modification beam, according to at least one embodiment. Method 500 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 500, can be performed responsive to instructions issued by a suitable computing device having a processing logic and memory to store the instructions.

At block 510, method 500 can include preparing a substrate (e.g., wafer 202), including but not limited to obtaining a bare substrate, preprocessing the bare substrate, e.g., polishing the substrate, removing stains and/or residue from the substrate, and/or the like, and/or performing any number of similar operations. At block 520, method 500 can continue with depositing one or more films/layers on the substrate. The layers can include a layer of conducting features, e.g., source lines to be used as part of memory cell (transistor) circuitry, alternating Nitride and Oxide layers, silicon layers, silicon-germanium alloy layers, and/or any suitable features. At block 530, method 500 includes collecting optical inspection data for the substrate and determining, using the optical inspection data, the map of deformation of a substrate e.g., displacement of a surface (e.g., the top surface) of a substrate as a function of some in-plane coordinates, e.g., polar coordinates z=h(r, ϕ), Cartesian coordinates, z=h(x, y), or any other suitable coordinates. In some implementations, the measured shape of the substrate can include decomposition of the shape over a suitable set of polynomials, e.g., Zernike polynomials, and obtaining a set of polynomial expansion coefficients, {Aⱼ}=(A₁, A₂, A₃), A₄, A₅, A₆, A₇, . . . , each coefficient in the set characterizing a degree of presence of a particular elemental geometric shape in the substrate's deformation.

In some embodiments, method 500 can include a decision-making block 540 to select a type of SCL to be used with the substrate. For example, a decision at block 540 can be made based on the coefficient that determines a degree of parabolicity of the deformation, e.g., coefficient A₄. If the substrate is curved downwards (towards the back side of the substrate, so that the edges of the substrate are lower than its center), A₄<0, a compressive SCL can be selected for the back side deposition. If A₄>0, a tensile SCL can be selected for back side deposition. In some embodiments, where a front side deposition is used, the selection of compressive SCL vs. tensile SCL can be reversed.

Operations of block 540 can also include determining a type of a material for the SCL to be deposited and a thickness d of the SCL. In some embodiments, this determination can be made based on multiple expansion coefficients (more than just the paraboloid bow coefficient A₄) from the set {Aⱼ} or the full profile h(r, ϕ). In one specific non-limiting example, the thickness d can be determined as follows. First, a target paraboloid deformation Ã₄ can be determined that is sufficient to overcompensate for the measured substrate deformation, e.g., for h(r, ϕ)<0, the following condition can be satisfied:

$${\tilde{A}}_{4} {Z}_{4} ( ρ , ϕ ) + h ( r , ϕ ) ≡ ( {\tilde{A}}_{4} + {A}_{4} ) {Z}_{4} ( ρ , ϕ ) + {A}_{5} {Z}_{5} ( ρ , ϕ ) + {A}_{5} {Z}_{6} ( ρ , ϕ ) + … > 0.$$

In other words, the target paraboloid deformation Ã₄ can be chosen sufficiently large to compensate for the paraboloid deformation (A₄), saddle deformation (A₅ and A₆) and the residual deformation (A₇, and higher coefficients). In some embodiments, the target paraboloid deformation Ã₄ can be selected with at least an excess magnitude A_{E} over the minimum needed to overcompensate for the substrate deformation, e.g.,

$${\tilde{A}}_{4} {Z}_{4} ( ρ , ϕ ) + h ( r , ϕ ) > {A}_{E} {Z}_{4} ( ρ , ϕ ) .$$

The excess magnitude A_{E} can be empirically selected and can depend on the specific material used for the SCL.

Once the target paraboloid deformation Ã₄ has been determined, the thickness d of the SCL can be selected using a calibration data that tabulates or otherwise defines a function d=ƒ(Ã₄). In some embodiments, the function ƒ(Ã₄) can be a non-linear function. In some embodiments, the function ƒ(Ã₄) can be a linear function, d=αÃ₄, with a coefficient of proportionality α determined based on mathematical modeling of elastic equations for specific SCL material(s), using empirical calibration, or any combination thereof. In some embodiments, thickness D of the SCL is selected to make deformation h_{corr}(r, ϕ) of a uniaxial type (e.g., cylindrical) after SCL deposition.

At block 550, method 500 can include determining, using the map of deformation of the substrate, settings for the stress-modification beam. The settings for the stress-modification beam can include a type of particles of the stress-modification beam, an energy of the particles of the stress-modification beam, and/or an angle of incidence of the particles of the stress-modification beam.

At block 560, method 500 can include determining (e.g., computing), using the map of deformation of the substrate, a dose map for a stress-modification beam, e.g., local irradiation dose maps n(x, y). The dose map can include a first feature having a first spatial scale (e.g., λₐₙ) along a first direction and a second feature having a second spatial scale (e.g., λ_{die}) along a second direction. The stress-modification beam can include ions, photons, electrons, and/or any combination thereof. A physics-based model, e.g., a model that solves the elastic plate equation for a substrate (e.g., using a finite difference method or other techniques of solving partial differential equations), can be used. The input in the model can include the measured (at block 530) deformation h(x, y) of the substrate and parameters of the SCL (determined at block 550), e.g., thickness and type of material of the SCL. The SCL can be modeled as a film that generates a uniform stress σ_{SCL} applied across the area of the substrate. The physics-based model can use the deformation h (x, y) and the uniform stress σ_{SCL} as the inputs and predict the stresses σ(x, y) that are to remain in the substrate after deposition of the SCL.

A spatial filter or a Fourier analyzer can then be applied to the predicted stress σ(x, y) to decompose the stress into a number of contributions associated with different scales, e.g., anisotropic stress σₐₙ(x; λₐₙ) associated with a small feature-level scale λₐₙ, stress σ_{die}(x, y; λ_{die}) associated with an intermediate die-level scale λ_{die}, stress σ_{waf}(x, y; λ_{waf}) associated with a large substrate-level scale λ_{waf}, and/or the like. Operations of block 560 can further include using a beam-substrate interaction model or a set of empirically determined heuristics to obtain a dose map n(x, y) that is to relax the stress σ(x, y) to a target stress distribution, e.g., a substrate with no (or insignificant) stress, σ(x, y)≈0. In some implementations, the beam-substrate interaction model can be a linear model, in which a sum of dose maps, n₁(x, y)+n₂(x, y), results in a stress modification Δσ₁+Δσ₂ that is the sum of stress modifications Δσ₁ and Δσ₂ achievable with the individual dose maps, n₁(x, y) and n₂(x, y). Correspondingly, the beam-substrate interaction model, applied to different multi-scale stresses, can generate various components of the dose map, e.g., nₐₙ(x), n_{die}(x, y), and n_{waf}(x, y), to mitigate the corresponding feature-level, dies-level, and substrate-level deformations. In some implementations, components of the dose map can be computed in conjunction with spatial directions. For example, one component of the dose map can be associated with the x-direction (and have a first spatial scale, e.g., λₐₙ) and another component of the dose map can be associated with the y-direction(and have at least one second spatial scale that different, e.g., larger, than the first spatial scale, e.g., λ_{die}, λ_{waf}).

At block 570, method 500 can continue with determining parameters of patterning of an SLC mask (e.g., mask 400 in FIGS. 4A-4E) to be deposited on the SCL, e.g., a profile d(x, y) of the thickness of the SCL mask. For example, a default peak flux j₀ of the stress-modification beam, dimensions of the beam (e.g., semi-widths of the beam a and b along main axes of the beam), and the scanning velocity v of the beam can be used as the baseline for the default dose no of the beam. The difference between no and the target doses nₐₙ(x), n_{die}(x, y), and n_{waf}(x, y) identified at block 560 can be computed and used to select the target thickness d(x, y) of the SLC mask patterning. For example, a larger thickness d(x, y) can be determined for those locations of the substrate that are to receive lower doses n(x) of stress-modification radiation and a lower thickness d(x, y) can be determined for those locations of the substrate that are to receive higher doses of radiation. In some implementations, e.g., as illustrated with FIGS. 4A-4E, thickness d(x, y) can have a fast-axis patterning 402 to control delivery of the doses of the radiation nₐₙ(x) that mitigate short-scale (feature-scale) anisotropic (e.g., cylindric, saddle) deformations and a slow-axis patterning 404 to control delivery of the doses of radiation n_{die}(x, y) that mitigate intermediate-scale (die-scale) deformations of the substrate.

In some implementations, delivery of large-scale (substrate-scale) doses n_{waf}(x, y) can be controlled by additional patterning of the SCL mask. In other embodiments, delivery of the large-scale doses can be facilitated by varying one or more beam parameters, e.g., peak flux j₀ of the beam, dimensions of the beam, local scanning velocity v (x, y) of the beam, and/or the like. In some implementations, the beam parameters can first be set based on the large-scale doses n_{waf}(x, y) that are to be delivered to the SCL. With the beam parameters set (which can include varying the scanning velocity v(x, y) with position on the substrate), the SCL patterning d(x, y) (e.g., both the fast-axis patterning and the slow-axis patterning) can be determined to ensure delivery of the correct short-scale and intermediate-scale doses nₐₙ(x) and n_{die}(x, y).

In determining the short-scale (anisotropy-correcting) doses nₐₙ(x), a processing device performing method 500 can determine an orientation of the axis of a cylindrical deformation relative to the substrate, e.g., a direction of the y-axis in FIG. 1B. The direction of the axis can then be used as the axis of the directional pattern(the direction along the ridges and/or trenches of FIGS. 2D-2E and FIGS. 4A-4E). Further parameters of the directional pattern can include (but need not be limited to) a pattern period (pitch), trench width, minimum and maximum thickness, and/or the like. Determining these parameters can be accomplished using modeling, simulations, solving the equations of elasticity (e.g., using a finite difference analysis), or by any other suitable techniques. A given anisotropic substrate deformation, e.g., deformation h_{corr}(r, ϕ) measured or predicted to occur after deposition of SCL of a given thickness d, can be corrected using more than a single set of the parameters. For example, increasing (decreasing) trench width for a given period and pattern thickness can result in decreased/increased stiffness of the SCL (e.g., in the direction perpendicular to the axis of the pattern), since the size of the protected areas in the SCL is decreased/increased. Similarly, decreased/increased stiffness of the SCL can be achieved by decreasing/increasing pattern thickness for given period and trench width. Increasing resolution by decreasing period (for a given aspect ratio of the width to the period) can result in a more uniform stress modification whereas increasing period can facilitate stress modulations of higher amplitude (e.g., larger difference between the maximum and minimum stress).

At block 580, the SCL of the selected (at block 540) thickness (e.g., uniform thickness) can be deposited on the back side of the substrate. (In some embodiments, SCL can be deposited on the front side of the substrate.)

At block 590, method 500 can include forming a spatially modulated mask on the SCL. The spatially modulated mask can include a first modulation associated with the first spatial scale, and a second modulation associated with the second spatial scale. In some implementations, at least one of the first modulation and the second modulation can include a plurality of raised portions and a plurality of recessed portions. Forming of the SCL mask can be performed by spin coating a photoresist, optical photolithography, imprint lithography, developing the photoresist, and/or other suitable techniques. In some embodiments, digital lithography techniques can be used instead of (or in addition to) contact printing. Optical lithography can include (but need not be limited to) contact photolithography (e.g., with a photoresist making a direct contact with the substrate), proximity photolithography (e.g., with a photoresist separated by a small gap from the substrate), and/or projection photolithography (e.g., with an optical element, such as a lens, positioned within the gap between the photoresist and the substrate).

At block 595, method 500 can continue with subjecting the spatially modulated mask and the SCL to the stress-modification beam to induce a spatial modulation of stress in the SCL, the spatial modulation of stress in the SCL causing mitigation of the deformation of the substrate. For example, operations of block 595 can include irradiating the SCL mask/SCL with a stress-modification beam to reduce the amount of stress in the substrate/films/mask structure and flatten this structure. In some implementations, application of the stress-modification beam can be performed with locally-changing beam parameters, e.g., scanning velocity, lateral beam dimensions, flux of the particles in the beam, and/or the like.

Variations modifications of method 500 are within the scope of this disclosure. In some implementations, operations of block 590 are not performed and a spatially modulated pattern of the first modulation and the second modulation in the SCL may be formed using a stress-modification beam without a mask, e.g., by subjecting the SCL to a spatially-varying dose of the stress-modification beam that has a size (e.g., radius or diameter) that is less than the first spatial scale and the second spatial scale.

Method 500 can further include various additional operations, as prescribed by the manufacturing specification, such as covering the SCL with ARC/photoresist layers, removing the remnants of the SCL mask, and/or performing any other suitable operations. In some embodiments, after the SCL is deposited, a shape of the substrate with the deposited SCL can be re-measured and the new expansion coefficients {Aⱼ} can be determined before parameters of the directional pattern are determined.

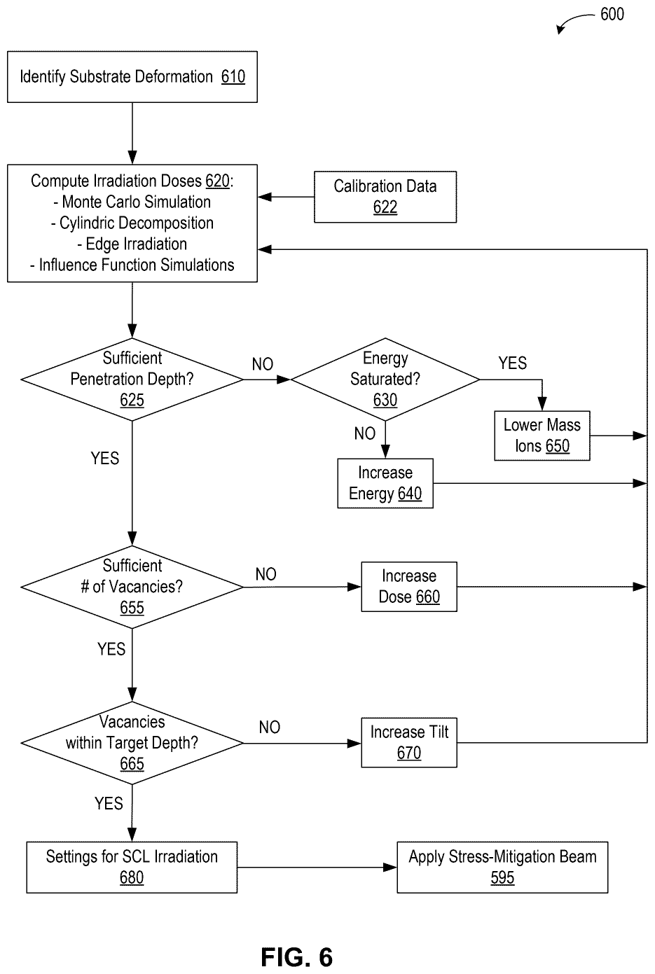

FIG. 6 is a flowchart illustrating an example method 600 of determining settings for beam irradiation, according to at least one embodiment. Method 600 can be performed as part of blocks 550-595 of method 500. At block 610, method 600 can include identifying some or all of a parabolic deformation (e.g., Zernike coefficients A₄), saddle deformation (e.g., Zernike coefficients A₅, A₆), and the residual deformation(e.g., Zernike coefficients A₇, A₈ . . . ) of a substrate, e.g., using profilometry measurements. (Operations of block 610 can be performed as part of block 530 of method 500).

At block 620, method 600 can continue with computing irradiation doses n(\vec{r}) for the SCL deposited on the substrate. (Operations of block 610 can be performed as part of block 560 of method 500). Operations of block 620 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of h_{WF}(\vec{r}), e.g., a decomposition of a saddle shape deformation into a parabolic deformation and a cylindrical deformation.

In some embodiments, irradiation doses n(\vec{r}) can be computed (and then applied at block 595) for selected edge regions of the SCL. For example, if the axis of cylindrical deformation, is the y-axis (as in FIG. 1B), the edge regions can be regions located within some vicinity of points x=±R, y=0, where R is the radius of the substrate. Irradiation doses n(\vec{r}) near other regions (e.g., near the center of the substrate) can be significantly lower and/or zero, in some embodiments. In some embodiments, the edge regions of the SCL have a width that is at or below 30% of a diameter of the substrate. In some embodiments, the edge regions of the SCL can be exposed to a spatially uniform dose of particles of the stress-modification beam, a radially-varying dose of particles of the stress-modification beam, or an azimuthally-varying dose of particles of the stress-modification beam. In some embodiments, irradiation doses n(\vec{r}) can be spread out more uniformly across the area of the substrate, e.g., can be non-zero both near the edges and near the middle of the substrate. In some embodiments, irradiation doses n(\vec{r}) can be uniform (constant) throughout the area of the substrate while the uniformity of stress modification is achieved by the deposited protective pattern having spatially-varying parameters (e.g., width W, period P, thickness T, etc.).

In some embodiments, irradiation doses n(\vec{r}) can be computed using an influence function G(\vec{r}; \vec{r}′), also known as the Green's function, which characterizes a response (e.g., deformation) of the substrate at a point \vec{r} of the substrate as caused by a point-like force applied at a point \vec{r}′ of the substrate. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference substrate. In some embodiments, a combination of multiple techniques of determining the influence function G(\vec{r}; \vec{r}′) can be used.

As a way of example, the Monte Carlo simulations for a structure (e.g., substrate with films and an SCL deposited thereon) can be performed for specific materials of the structure (e.g., silicon substrate, stack of films, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the SCL (e.g., a default velocity of scanning and a default scanning pattern), and the like.

In some embodiments, various techniques of irradiation dose computations can use calibration data 622 collected for actual irradiation performed for various types of the irradiation beams, energies of the irradiation beams, types and materials of structures being irradiated, angles of beam incidence on the structures, and/or the like. In some embodiments, calibration data 622 can be statistically preprocessed. For example, various measurements can be collected for multiple substrate/films/SCL materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 620 can include sampling from the stored distributions and identifying a likelihood that a target stress modification will be achieved with the default settings of conditions of beam irradiation of a SCL of a given type and thickness. Method 600 can include several verification operations designed to determine whether the target stress can be achieved without detrimentally affecting properties of the substrate/films. For example, at block 625, method 600 can include verifying if the penetration depth of the selected (e.g., default) type of particles is sufficient. For example, the penetration depth is to be at least a certain fraction of the thickness of the SCL, e.g., 20%, 30%, 50%, 80%, or more of that thickness. In some embodiments the penetration depth can be up to 100% of the thickness. If the energy is insufficient, method 600 can include checking, at block 630, if the irradiation beam source is capable of outputting particles of a higher energy. If higher energies are available, method 600 can continue with increasing the energy of the particles (block 640) and repeating irradiation dose computations of block 620 for the increased energy. If the maximum energy of the irradiation beam source has already been reached, method 600 can continue with replacing (at block 650) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 655, method 600 can include verifying whether the number of expected formed vacancies is sufficient. To verify sufficiency, method 600 can assess stress modification caused by formed vacancies. In one embodiment, method 600 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 600 can include increasing a dose of particles (at block 660) and repeating irradiation dose computations of block 620 for the increased dose.

At block 665, method 600 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the substrate/films and affecting properties of the substrate/films. If the vacancies are to be formed at depths that exceed the target depth, method 600 can include (at block 670) increasing an angle of incidence (e.g., by tilting the irradiation beam) to keep vacancies (as well as substitution impurities) to a shallower region of the SCL.

Blocks 620-670 can be repeated multiple times until irradiation dose computations of block 620 are determined to be sufficient that the desired stress modification can be achieved, e.g., that the reduction in the tensile stress of the SCL is such that the deformation of the substrate is eliminated or at least reduced to an acceptable tolerance. The final settings for SCL irradiation (block 680) determined from irradiation dose computations can then be used for irradiation of the SCL with the stress-modification beam (at block 595).

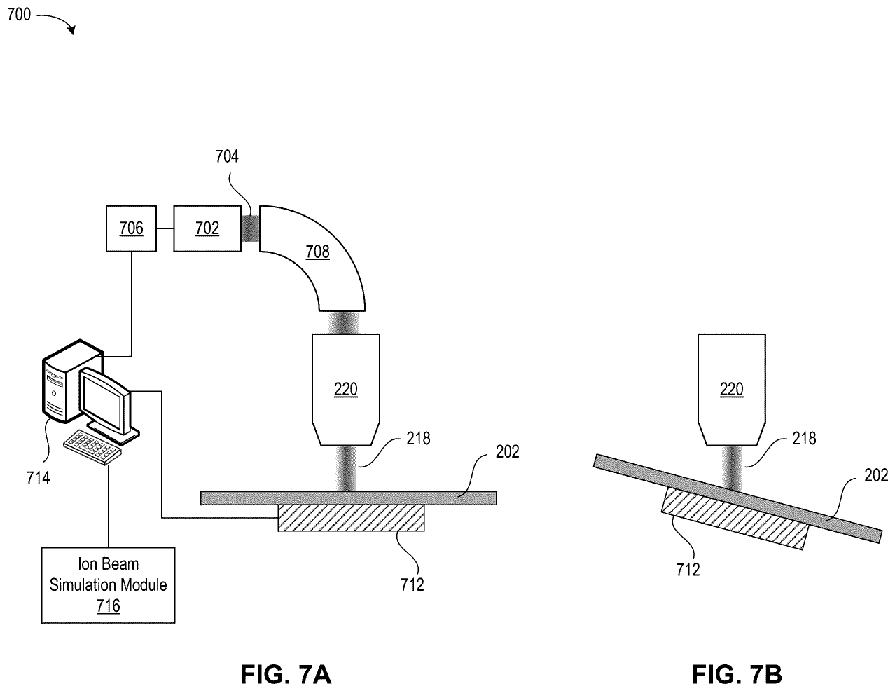

FIG. 7A illustrates schematically an irradiation system 700 capable of performing irradiation of stress compensation layers, according to at least one embodiment. Irradiation system 700 can include collimating and focusing column 220 of FIG. 2E. Irradiation system 700 can further include a beam source 702 for producing a source beam 704. Beam source 702 can include a chamber for generating ions (e.g., a plasma chamber), a light source for generating photons (e.g., a laser, laser diode, lamp, etc.), a heated filament for producing electrons, and/or any other source for the particles of a type deployed in specific stress-modification techniques of the instant disclosure. Beam source 702 can be powered by a power element 706 and can include an extraction electrode assembly (not shown). Irradiation system 700 can include a mass spectrometer 708 (e.g., in the instances where beam source 702 produces charged particles, such as electrons or ions) and a collimating and focusing column 220. Collimating and focusing column 220 can direct stress-modification beam 218 to wafer 202. Wafer 202 can be supported by a support stage 712. In some embodiments, support stage 712 and wafer 202 can remain stationary during irradiation of wafer 202 by stress-modification beam 218 while components of irradiation system 700 can be repositioned relative to wafer 202. In some embodiments, irradiation system 700 can be stationary while support stage 712 can reposition wafer 202. In some embodiments, stress-modification beam 218 can have intensity (e.g., light intensity) that is modulated by changing intensity of beam source 702 and/or placing a partially absorbing or partially reflecting material at some location between beam source 702 and wafer 202. This enables delivery of local irradiation doses n(x, y) to various locations of wafer 202. Scanning with stress-modification beam 218 can occur along multiple directions, e.g., along x-axis and along y-axis according to any suitable predetermined pattern, e.g., back- and forth along x-axis, in a spiral pattern, and so on. In various embodiments, stress-modification beam 218 can be scanned with a frequency of several Hz, tens of Hz, hundreds of Hz, thousands of Hz, or more.

Operations of irradiation system 700 can be controlled by a controller 714, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 714 can control operations of power element 706, support stage 712, and/or various other components and modules of irradiation system 700. Controller 714 can include a stress-modification module 716 capable of performing simulations that determine a target intensity of stress-modification beam 218 to be used to mitigate various wafer deformations. In some embodiments, as illustrated in FIG. 7B, support stage 712 can impart a tilt, e.g., in one or two spatial directions to wafer 202 to change an angle of incidence of stress-modification beam 218 relative to wafer 202. In some embodiments, instead of tilting wafer 202, controller 714 can cause a tilt of stress-modification beam 218 relative to wafer 202.

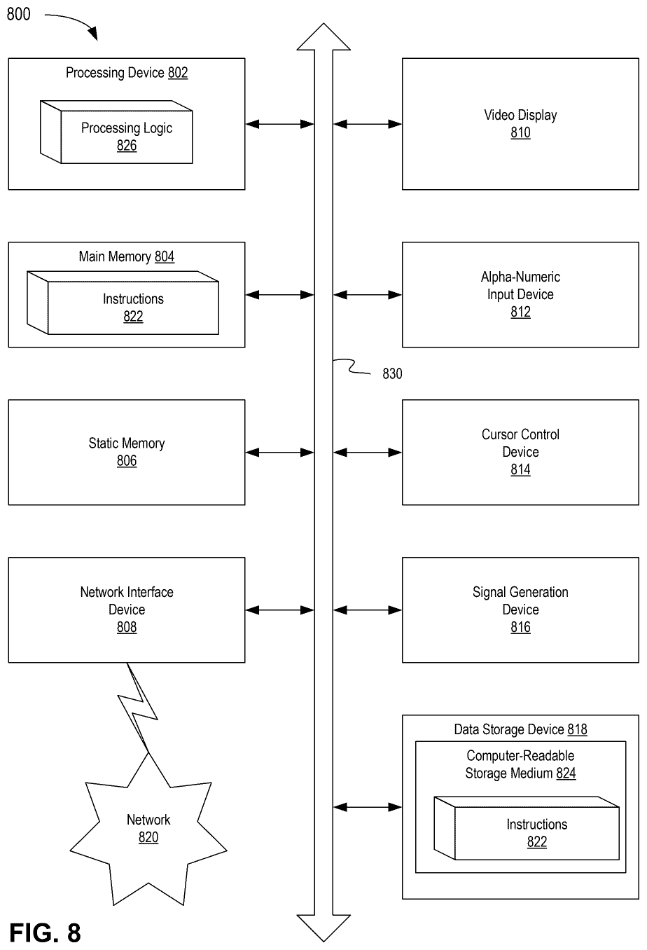

FIG. 8 depicts a block diagram of an example computer system 800 capable of supporting operations of the present disclosure, according to at least one embodiment. In various illustrative examples, example computer system 800 can be or include controller 714 of FIG. 7. Example computer system 800 can be connected to other computer systems in a LAN, an intranet, an extranet, and/or the Internet. Computer system 800 can operate in the capacity of a server in a client-server network environment. Computer system 800 can be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 800 can include a processing device 802 (also referred to as a processor or CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which can communicate with each other via a bus 830.

Processing device 802 represents one or more general-purpose processing devices such as a microprocessor, central processing unit, or the like. More particularly, processing device 802 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. In accordance with one or more aspects of the present disclosure, processing device 802 can include a processing logic 826 configured to execute instructions (e.g., instructions 822) implementing example method 500 of mitigation of anisotropic wafer stress and deformation using stress-compensation beams with directional pattern and/or method 600 of determining settings for beam irradiation.

Example computer system 800 can further comprise a network interface device 808, which can be communicatively coupled to a network 820. Example computer system 800 can further comprise a video display 810 (e.g., a liquid crystal display (LCD), a touch screen, or a cathode ray tube (CRT)), an alphanumeric input device 812 (e.g., a keyboard), a cursor control device 814 (e.g., a mouse), and an acoustic signal generation device 816 (e.g., a speaker).

Data storage device 818 can include a computer-readable storage medium (or, more specifically, a non-transitory computer-readable storage medium) 824 on which is stored one or more sets of executable instructions 822. In accordance with one or more aspects of the present disclosure, executable instructions 822 can comprise executable instructions implementing example method 500 of mitigation of anisotropic wafer stress and deformation using stress-compensation beams with directional pattern and/or method 600 of determining settings for beam irradiation.

Executable instructions 822 can also reside, completely or at least partially, within main memory 804 and/or within processing device 802 during execution thereof by example computer system 800, main memory 804 and processing device 802 also constituting computer-readable storage media. Executable instructions 822 can further be transmitted or received over a network via network interface device 808.

While the computer-readable storage medium 824 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus can be specially constructed for the required purposes, or it can be a general purpose computer system selectively programmed by a computer program stored in the computer system. Such a computer program can be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems can be used with programs in accordance with the teachings herein, or it can prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages can be used to implement the teachings of the present disclosure.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but can be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
form a stress-compensation layer (SCL) on a substrate;
determining, using a map of deformation of the substrate, a dose map for a stress-modification beam, wherein the dose map comprises a first feature having a first spatial scale along a first direction and a second feature having a second spatial scale along a second direction; and
forming, using a stress-modification beam, a spatially modulated pattern in the SCL, wherein the spatially modulated pattern causes modification of the deformation of the substrate and comprises:
a first modulation associated with the first spatial scale, and
a second modulation associated with the second spatial scale.

2. The method of claim 1, wherein the stress-modification beam comprises at least one of: a beam of ions, a beam of photons, or a beam of electrons.

3. The method of claim 1, wherein forming the spatially modulated pattern in the SCL comprises:
forming a spatially modulated mask on the SCL; and
subjecting the spatially modulated mask and the SCL to the stress-modification beam.

4. The method of claim 3, wherein at least one of the first modulation or the second modulation is caused by a plurality of raised portions and a plurality of recessed portions of the spatially modulated mask interacting with the stress-modification beam.

5. The method of claim 3, wherein forming the spatially modulated mask on the SCL comprises:
depositing a mask on the SCL; and
forming at least one of the first modulation or the second modulation using at least one of:
contact photolithography,
proximity photolithography,
projection photolithography,
imprint lithography, or
digital lithography.

6. The method of claim 1, wherein forming the spatially modulated pattern in the SCL comprises:
subjecting the SCL to a spatially-varying dose of the stress-modification beam, wherein the stress-modification beam has a size that is less than the first spatial scale and the second spatial scale.

7. The method of claim 1, wherein the stress-modification beam has a cross-section that is less than 1 mm.

8. The method of claim 1, wherein the first spatial scale is less than 1 micron.

9. The method of claim 8, wherein the first spatial scale is less than 100 nanometers.

10. The method of claim 1, wherein the second spatial scale is greater than 1 micron.

11. The method of claim 10, wherein the second spatial scale is greater than 10 microns.

12. The method of claim 1, further comprising:
collecting optical inspection data for the substrate; and
determining, using the optical inspection data, the map of deformation of a substrate.

13. The method of claim 1, further comprising:
determining, using the map of deformation of the substrate, settings for the stress-modification beam, wherein the settings for the stress-modification beam comprise one or more of:
a type of particles of the stress-modification beam,
an energy of the particles of the stress-modification beam, or
an angle of incidence of the particles of the stress-modification beam.

14. A system comprising:
a memory; and
a processing device communicatively coupled to the memory, wherein the processing device is to cause performance of operations comprising:
forming a stress-compensation layer (SCL) on a substrate;
determining, using a map of deformation of the substrate, a dose map for a stress-modification beam, wherein the dose map comprises a first feature having a first spatial scale along a first direction and a second feature having a second spatial scale along a second direction;
forming a spatially modulated mask on the SCL, wherein the spatially modulated mask comprises:
a first modulation associated with the first spatial scale, and
a second modulation associated with the second spatial scale; and
subjecting the spatially modulated mask and the SCL to the stress-modification beam to induce a spatial modulation of stress in the SCL, wherein the spatial modulation of stress in the SCL causes modification of the deformation of the substrate.

15. The system of claim 14, wherein the stress-modification beam comprises at least one of: a beam of ions, a beam of photons, or a beam of electrons.

16. The system of claim 14, wherein the stress-modification beam comprises at least one of: a beam of ions, a beam of photons, or a beam of electrons.

17. The system of claim 16, wherein forming the spatially modulated mask on the SCL comprises:
depositing a mask on the SCL; and
forming at least one of the first modulation or the second modulation using at least one of:
contact photolithography,
proximity photolithography,
projection photolithography,
imprint lithography, or
digital lithography.

18. The system of claim 14, wherein the stress-modification beam has a cross-section that is less than 1 mm.

19. The system of claim 14, wherein the first spatial scale is less than 1 micron and is greater than 1 micron.

20. The system of claim 14, wherein the operations further comprise:
collecting optical inspection data for the substrate; and
determining, using the optical inspection data, the map of deformation of a substrate.

21. The system of claim 14, wherein the operations further comprise:
determining, using the map of deformation of the substrate, settings for the stress-modification beam, wherein the settings for the stress-modification beam comprise one or more of:
a type of particles of the stress-modification beam,
an energy of the particles of the stress-modification beam, or an angle of incidence of the particles of the stress-modification beam.

22. A semiconductor manufacturing system comprising one or more processing chambers, the semiconductor manufacturing system to:
form a stress-compensation layer (SCL) on a substrate;
determine, using a map of deformation of the substrate, a dose map for a stress-modification beam, wherein the dose map comprises a first feature having a first spatial scale along a first direction and a second feature having a second spatial scale along a second direction; and
form, using a stress-modification beam, a spatially modulated pattern in the SCL, wherein the spatially modulated pattern causes modification of the deformation of the substrate and comprises:
a first modulation associated with the first spatial scale, and
a second modulation associated with the second spatial scale.
